(19) United States
(12) Patent Application Publication
(10) Pub. No.: US 2012/0068771 A1
(43) Pub. Date: Mar. 22, 2012

(54) HETEROGENEOUS INTEGRATION OF HARMONIC LOADS AND TRANSISTOR FEEDBACK FOR IMPROVED AMPLIFIER PERFORMANCE

(76) Inventors: James M. Carroll, Allen, TX (US); John G. Heston, Murphy, TX (US); Jon Edward Mooney, Dallas, TX (US)

(21) Appl. No.: 12/888,292

(22) Filed: Sep. 22, 2010

(51) Int. Cl. H03F 3/16; H05K 3/30

(52) U.S. Cl. 330/291; 29/832

(57) ABSTRACT

An RF power amplifier device in which the circuit is provided on two separate dies which are attached together vertically. According to one embodiment of the present invention, the RF power amplifier includes a first die including an amplifying circuit for amplifying an RF signal, and a second die including at least one circuit component coupled to the amplifying circuit. The first die is vertically coupled to the second die, and the second die may be a flip chip and include harmonic loads and/or feedback circuit.

### BACKGROUND

1. Field

Aspects of embodiments of the present invention relate to amplifiers, and, in particular, radio-frequency power amplifiers for use in wireless communication apparatus.

2. Description of Related Art

A radio-frequency (RF) power amplifier is used in wireless communication devices to amplify an input RF signal to be transmitted by an antenna. Generally, efficiency and output power are the key parameters of the RF power amplifier. In order to improve uniformity and reduce the size of the communication devices, the RF power amplifier may be implemented as a monolithic microwave integrated circuit.

It is known that both the fundamental frequency of the RF signal and the harmonic components of the fundamental frequency should be considered and designed to certain impedance terminations in order to increase the efficiency of the RF power amplifier. It has been suggested that the efficiency of the RF power amplifier may be increased when the output circuit and/or input circuit of the RF power amplifier include impedance control circuitry that is designed in consideration of the fundamental frequency of the output signal as well as its harmonic components. For example, impedance control circuits (e.g., harmonic loads) may be connected to the input/output of the RF power amplifier to adjust the impedance of the input/output terminals at those harmonic frequencies of the RE power amplifier to increase total performance.

In some RF power amplifier designs, feedback may be utilized to provide further control of the output signal and to increase stability of the amplifier. For example, in a linear RF power amplifier, negative feedback may be utilized to minimize the level of amplitude distortion and AM-to-PM conversion. Furthermore, feedback including active or switching components such as MEMS may be used to provide further control of the RF power amplifier.

However, it is not always practical or desirable to incorporate additional impedance control and feedback circuitry monolithically to an RF amplifier implemented as an integrated circuit chip because the additional circuits may adversely affect the layout or in-band performance of the circuit. The additional circuitry may cause matching networks of the RF amplifier to be bigger, more lossy, or sometimes even impractical to be implemented monolithically.

### SUMMARY

Aspects of embodiments of the present invention are directed toward an RF power amplifier circuit fabricated on a first die and other circuits on a second die which is vertically integrated with the first die, thereby improving the circuit layout and/or performance of the RF power amplifier on the first die.

In some embodiments of the present invention, the circuits fabricated on the second die may be harmonic loads, feedback (e.g., shunt feedback), transistor feedback, bias chokes, or other suitable circuits. The vertical dimension takes the circuit fabricated on the second die (e.g., the harmonic loads, or feedback) out of the planar circuit (e.g., matching networks) on the first die.

An embodiment of the present invention provides an RF amplifier that includes a first die including an amplifying circuit for amplifying an RF signal, and a second die including at least one circuit component of the RF amplifier electrically coupled to the amplifying circuit. The first die is vertically coupled to the second die.

According to an embodiment, the second die may be a flip chip.

According to an embodiment, the first die may include a plurality of first contacts electrically coupled to the amplifying circuit, and the second die may include a plurality of second contacts electrically coupled to the at least one circuit component. The first contacts may be electrically coupled to the second contacts.

According to an embodiment, the at least one circuit component may include at least one harmonic load.

According to an embodiment, the at least one circuit component may include a feedback circuit.

According to an embodiment, the at least one circuit component may include at least a part of a passive or active bias circuit.

According to an embodiment, the first die may include a substrate material that is different from that of the second die.

According to an embodiment, the first die and the second die may include a same substrate material.

An embodiment of the present invention provides a method of fabricating an RF amplifier. The method includes fabricating an amplifying circuit for amplifying an RF signal on a first die, fabricating at least one circuit component of the RF amplifier on a second die, and electrically coupling the at least one circuit component to the amplifying circuit by vertically coupling the second die to the first die.

According to an embodiment, the method may further include fabricating a plurality of first contacts electrically coupled to the amplifying circuit on the first die, and fabricating a plurality of second contacts electrically coupled to the at least one circuit component on the second die. The first contacts may be electrically coupled to the second contacts.

### BRIEF DESCRIPTION OF THE DRAWINGS

The features and aspects of embodiments of the present invention will be more apparent from the following detailed description in conjunction with the accompanying drawings, in which:

FIG. 1a is a schematic diagram of an exemplary RF power amplifier.

FIG. 1b is a schematic diagram of the RF power amplifier of FIG. 1a connected to harmonic loads.

FIG. 1c is a schematic diagram of the RF power amplifier of FIG. 1a connected to a shunt feedback.

FIG. 1d is a schematic diagram of the RF power amplifier of FIG. 1a connected to external bias chokes.

FIG. 2a is a perspective view of two dies on which the RF power amplifier of FIG. 1a is fabricated on one of the dies, according to an embodiment of the present invention.

FIG. 2b is a flow chart illustrating a typical process of attaching a flip clip to another chip or die.

FIG. 3a is a perspective view of one of the dies of FIG. 2a.

FIG. 3b is another perspective view of the die of FIG. 3a flipped upside down.

FIG. 4a is a perspective view of the dies of FIG. 2a aligned to each other.

FIG. 4b is a perspective view of the dies of FIG. 4a attached to each other.

### DETAILED DESCRIPTION

Exemplary embodiments will now be described more fully hereinafter with reference to the accompanying drawings. As those skilled in the art would realize, the described embodiments may be modified in various different ways, all without departing from the spirit or scope of the present invention.

Exemplary embodiments of the present invention provide an RF power amplifier device in which an RF power amplifier is fabricated on a first die or wafer, and its other circuit components are fabricated on a second die or wafer that is vertically connected to the first die. In one embodiment, the second die may be a flip chip. In some embodiments, the circuit components fabricated on the second die may include harmonic loads, transistor feedback circuit, and other circuits suitable to be fabricated on different dies. The first and second dies may be separately fabricated and vertically connected to each other such that the RF power amplifier on the first die is electrically connected to the other circuit components on the second die. The first and second dies may be fabricated by methods and materials generally known in the art, and the circuits respectively fabricated on the first and second dies may be electrically connected to each other by techniques that are generally known in the art. While the exemplary embodiments described in detail herein incorporate an RF power amplifier, the application of the present invention to other circuits will be apparent to those skilled in the art.

### Exemplary Embodiment

Harmonic loads and transistor feedback are important mechanisms that are commonly used by amplifier designers to improve the performance of an RF amplifier circuit. However, there are also negative effects when harmonic loads and transistor feedback are integrated into the layout of a monolithic integrated circuit. For example, because of the low-Q of integrated passives at the higher RF frequencies, the harmonic loads or feedback may actually be very difficult or even impossible to create monolithically with the performance needed by the circuit.

That is, in some designs, it is impractical to incorporate the necessary circuitry for harmonic loads or feedback without compromising the layout and even in-band performance of the matching networks. Utilizing the vertical dimension to provide the above discussed functions gives the designer an additional level of design freedom. The harmonic loads and feedback may be designed separately and attached in just the locations where it is needed. This hybrid implementation of the harmonic loads and feedback allow them to be created out of a material different than the other portion of the RF circuit that is fabricated on a different die. For example, a high dielectric constant material may be used to create a harmonic load that is smaller than possible on the main circuit. Better thermal and higher Q materials may be used to improve the overall performance of the circuit. The hybrid aspect of the embodiments of the present invention also allows for a designer to have a variety of harmonic loads or feedback values, and they may be swapped out depending on the circuit needed to tune the overall circuit for the best performance.

An exemplary embodiment is described below in more detail to illustrate an RF power amplifier circuit in which harmonic loads and transistor feedback are fabricated on a die that is different from that of the RF power amplifier. The following exemplary embodiment provides a new approach to use the vertical direction to integrate that functionality without compromising the layout of the matching networks of the RF power amplifier.

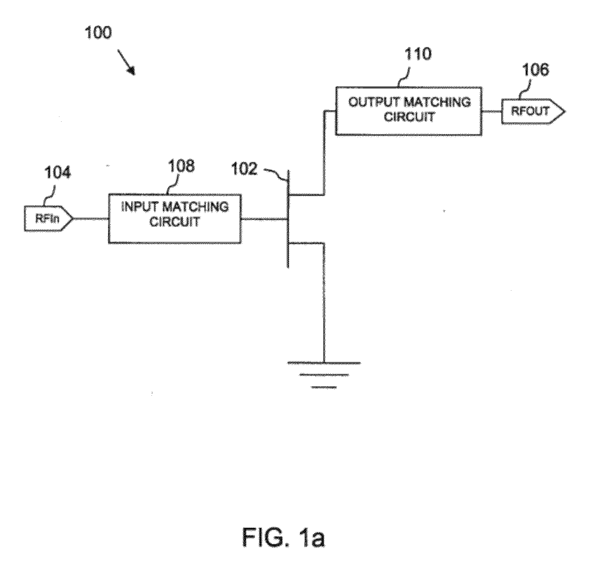

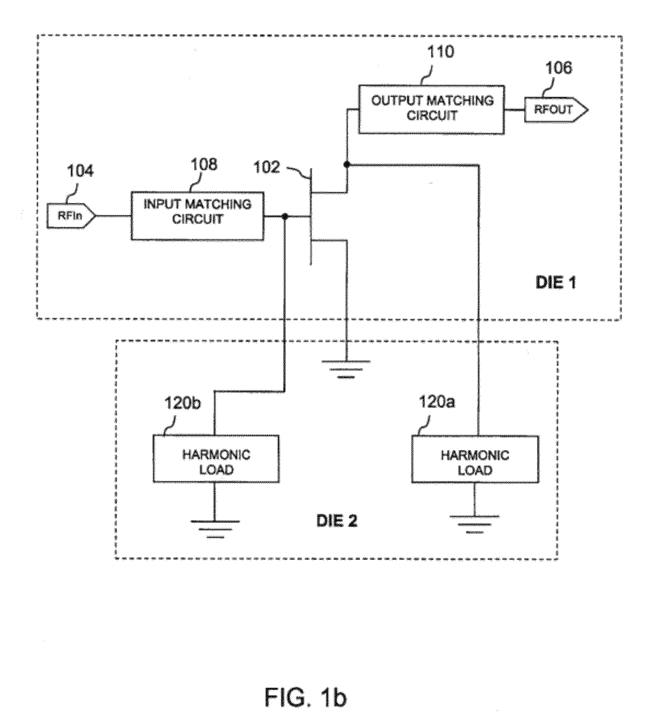

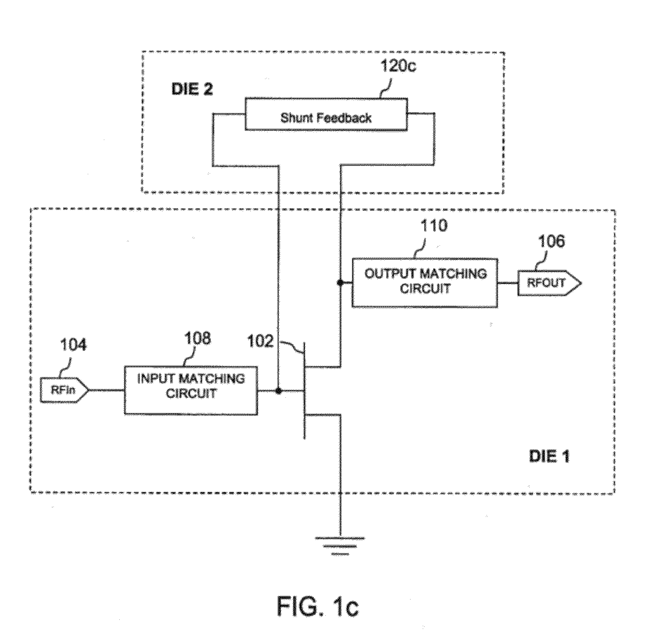

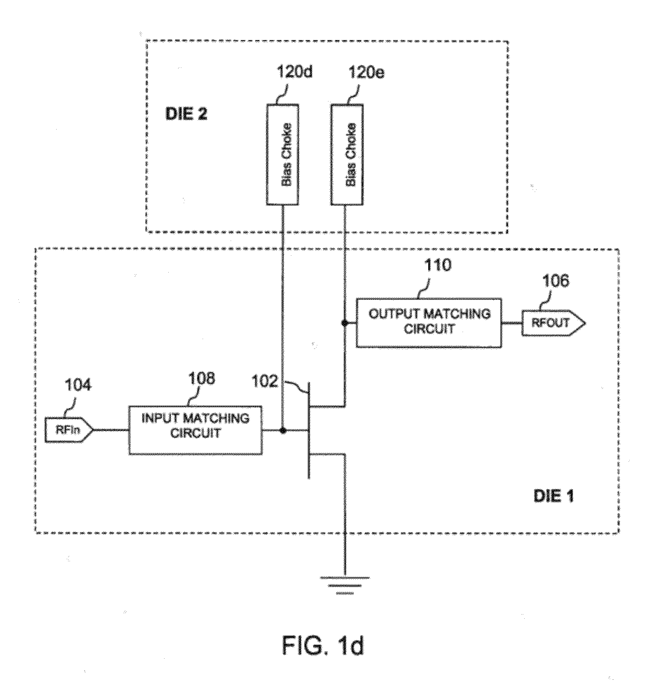

FIG. 1a is a schematic diagram of an exemplary RF power amplifier.

Referring to FIG. 1a, an RF power amplifier 100 includes an amplifier transistor 102, an input 104, an output 106, an input matching circuit 108, and an output matching circuit 110.

FIG. 1b is a circuit diagram of the exemplary RF power amplifier 100 of FIG. 1a connected to harmonic loads 120a and 120b respectively coupled to the drain and gate of the amplifier transistor 102 (e.g., a FET device). Here, the RF power amplifier 100 is fabricated on a first die (die 1), and the harmonic loads 120a and 120b are fabricated on a second die (die 2). However, the harmonic loads may be integrated elsewhere in the matching circuits in other embodiments.

FIG. 1c is a circuit diagram of the exemplary RF power amplifier 100 of FIG. 1a connected to a shunt feedback 120c coupled between the gate and drain of the amplifier transistor 102. Here, the RF power amplifier 100 is fabricated on a first die (die 1), and the shunt feedback 120c is fabricated on a second die (die 2).

FIG. 1d is a circuit diagram of the exemplary RF power amplifier 100 of FIG. 1a connected to external bias chokes 120d and 120e respectively coupled to the gate and drain of the amplifier transistor 102. Here, the RF power amplifier 100 is fabricated on a first die (die 1), and the external bias chokes 120d and 120e are fabricated on a second die (die 2).

One skilled in the art would appreciate that the present invention is not limited to the embodiments of FIGS. 1a, 1b, 1c, and 1d; to the contrary, the present invention may be applied to other suitable circuits.

As illustrated in the embodiments of FIGS. 1a-1d, the harmonic loads 120a and 120b, shunt feedback 120c, external bias chokes 120d and 120e, and/or the transistor feedback may be fabricated on a separate die (e.g., second die) such that the primary circuit (e.g., the RF power amplifier transistor, input matching circuit, output matching circuit, etc.) may be fabricated on a different die (e.g., first die). Here, the first die and second die may be formed of different materials, and the circuits on the first and second dies may be fabricated by techniques generally known in the art. For fabricating the RF power amplifier 100, harmonic loads 120a and 120b, shunt feedback 120c, and/or external bias chokes 120d and 120e, the first and second dies may include GaAs type semiconductor or other suitable semiconductors such as silicon type semiconductor. Furthermore, in some embodiments, the first and second dies may include different semiconductors. For example, the first die may include GaAs type semiconductor, and the second die may include silicon type semiconductor or dielectric based materials such alumina or printed wiring board. After the RF power amplifier 100 is fabricated on the first die and the harmonic loads 120a and 120b, shunt feedback 120c, and/or external bias chokes 120d and 120e are fabricated on the separate second die, the circuit on the second die may be vertically attached to the circuit on the first die. For example, the second die may be a flip chip which is attached to the first die at the chip level or by wafer bonding with metal vias making the connection on a wafer level.

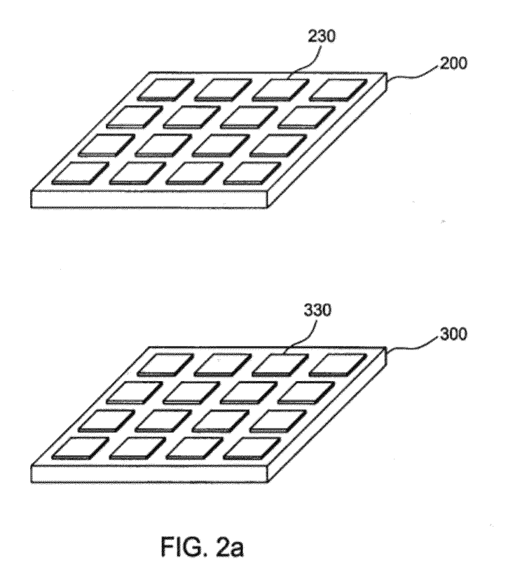

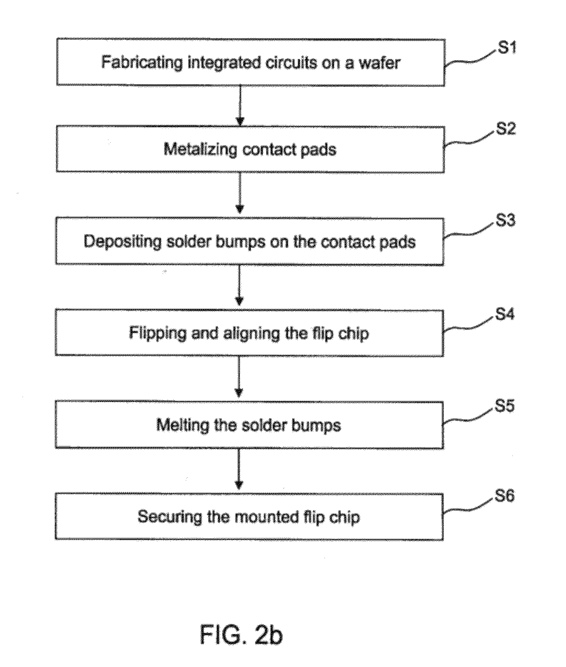

FIG. 2a is a perspective view of first and second dies according to an embodiment of the present invention. It will be appreciated that the relative sizes of the various elements depicted are not to scale, but may be exaggerated for the ease of illustration.

In FIG. 2a, the RF power amplifier 100 and a plurality of first electrical contacts 230 (e.g., bonding pads) are fabricated on the first die 200. The first electrical contacts 230 are electrically connected with the RF power amplifier 100. The harmonic loads 120a and 120b, shunt feedback 120c, and/or external bias chokes 120d and 120e and a plurality of second electrical contacts 330 (e.g., bonding pads) are fabricated on the second die 300. The second electrical contacts 330 are electrically connected with the circuits on the second die. However, the present invention is not limited to the above embodiment. Other suitable circuits may be fabricated respectively on the first and second dies. When the electrical contacts 230 and 330 are electrically connected together, the circuits on the first and second dies are electrically connected together via the electrical contacts 230 and 330. In one embodiment, the first die 200 may be attached to the second die 300 as a flip chip.

Flip chip is a method for interconnecting electrical devices or dies, such as IC chips, to external circuitry with solder bumps that have been deposited onto contact pads (e.g., chip pads or bonding pads). The solder bumps are deposited on the contact pads on the top side of the wafer during the final wafer processing step. In order to mount the chip (i.e., flip chip) to external circuitry (e.g., a circuit board or another chip or wafer), it is flipped over so that its top side faces down, and aligned so that its pads or solder bumps align with matching pads or contacts on the external circuit, and then the solder is flowed to complete the interconnect.

FIG. 2b is a flow chart illustrating a typical process of attaching a flip clip to another chip or die.

Referring to FIG. 2b, the process includes: S1) fabricating integrated circuits on a wafer; S2) metalizing contact pads on the surface of the flip chip; S3) depositing solder bumps on each of the contact pads; S4) flipping the flip chip over and aligning the flip chip so that the solder bumps are facing the corresponding connectors or contact pads on the external circuitry; S5) melting the solder bumps (e.g., by using hot air reflow); and S6) securing the mounted flip chip using an electrically-insulating adhesive.

The above described flip chip assembly method is only an illustrative embodiment, and the present invention is not limited thereto. For instance, the flip chip assembly may also be accomplished by thermo-compression bonding.

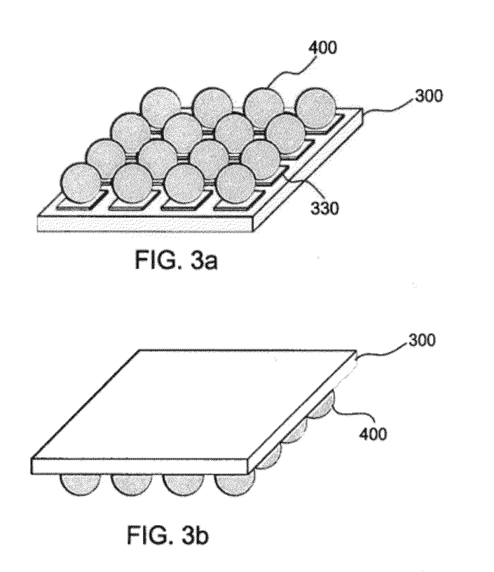

FIG. 3a is a perspective view of the second die 300 according to an embodiment of the present invention.

Referring to FIG. 3a, a plurality of solder bumps 400 are attached to the second electrical contacts 330 before the first and second dies 200 and 300 are attached to each other. However, the solder bumps 400 may be first attached to the first electrical contacts 230 of the first die 200 before the first and second dies are attached to each other. The solder bumps 400 may include tin-lead solder or other suitable solder materials generally known in the art.

FIG. 3b is another perspective view of the second die 300 flipped upside down.

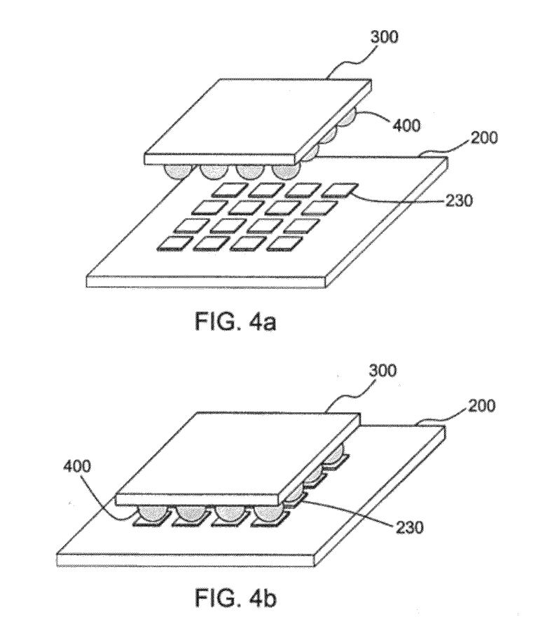

FIG. 4a is a perspective view of the first and second dies 200 and 300 aligned to each other, and FIG. 4b is a perspective view of the first and second dies 200 and 300 attached to each other.

Referring to FIG. 4a, the second die 300 is flipped upside down and is aligned with the first die 200 so that the solder bumps 400 are aligned with the first electrical contacts 230 on the first die 200. Referring the FIG. 4b, the first and second dies are attached to each other such that the first contacts 230 of the first die 200 are electrically connected to the second contacts 330 of the second die 300 via the solder bumps 400. Subsequently, heat is applied to melt the solder bumps 400 to form a secure connection between the first contacts 230 and the second contacts 330. However, the present invention is not limited to using solder bumps. In some embodiments, other suitable electrical connectors, such as metal thermo-compression posts, may be used.

According to the above described exemplary embodiments, performance and layout of an RF power amplifier device may be improved by fabricating harmonic loads, shunt feedback, external bias chokes, and/or transistor feedback of the amplifier device on a separate die which is vertically integrated with another die on which the amplifier is fabricated. According to the exemplary embodiments, the hybrid amplifier may be fabricated with dies that include different materials such that the respective circuits on the separate dies may be optimized.

Although exemplary embodiments of the present invention have been illustrated, it should be understood that many variations and modifications may be made in those embodiments without departing from the spirit and scope of the present invention as set forth in the following claims and their equivalents.

What is claimed is:

1. An RF amplifier comprising:
a first die comprising an amplifying circuit for amplifying an RF signal; and
a second die comprising at least one circuit component of the RF amplifier electrically coupled to the amplifying circuit, wherein the first die is vertically coupled to the second die.

2. The RF amplifier of claim 1, wherein the second die is a flip chip.

3. The RF amplifier of claim 1,
wherein the first die comprises a plurality of first contacts electrically coupled to the amplifying circuit, and the second die comprises a plurality of second contacts electrically coupled to the at least one circuit component, and
wherein the first contacts are electrically coupled to the second contacts.

4. The RF amplifier of claim 1, wherein the at least one circuit component comprises at least one harmonic load.

5. The RF amplifier of claim 1, wherein the at least one circuit component comprises a feedback circuit.

6. The RF amplifier of claim 1, wherein the at least one circuit component comprises at least a part of a passive or active bias circuit.

7. The RF amplifier of claim 1, wherein the first die comprises a substrate material that is different from that of the second die.

8. The RF amplifier of claim 1, wherein the first die and the second die comprise a same substrate material.

9. A method of fabricating an RF amplifier comprising:
fabricating an amplifying circuit for amplifying an RF signal on a first die;
fabricating at least one circuit component of the RF amplifier on a second die; and
electrically coupling the at least one circuit component to the amplifying circuit by vertically coupling the second die to the first die.

10. The method of claim 9, wherein the second die is a flip chip.

11. The method of claim 9, further comprising:
fabricating a plurality of first contacts electrically coupled to the amplifying circuit on the first die; and
fabricating a plurality of second contacts electrically coupled to the at least one circuit component on the second die,
wherein the first contacts are electrically coupled to the second contacts.

12. The method of claim 9, wherein the at least one circuit component comprises at least one harmonic load.

13. The method of claim 9, wherein the at least one circuit component comprises a feedback circuit.

14. The method of claim 9, wherein the first die comprises a substrate material that is different from that of the second die.

15. The method of claim 9, wherein the first die and the second die comprise a same substrate material.
